(19) United States
(12) Patent Application Publication
(10) Pub. No.: US 2025/0133722 A1
(43) Pub. Date: Apr. 24, 2025

(54) SEMICONDUCTOR MEMORY DEVICE AND METHOD FOR FABRICATING THE SAME

(71) Applicant: Samsung Electronics Co., Ltd., Suwon-si (KR)

(72) Inventors: Eui-Hyuk Kim, Suwon-si (KR); Ji Yeon Chang, Suwon-si (KR); Hyeon Song Cha, Suwon-si (KR)

(21) Appl. No.: 18/777,950

(22) Filed: Jul. 19, 2024

(30) Foreign Application Priority Data
Oct. 23, 2023 (KR) 10-2023-0141822

(51) Int. Cl. H10B 12/00

(52) U.S. Cl. CPC H10B 12/315; H10B 12/033

(57) ABSTRACT

A semiconductor memory device includes a storage pad on a substrate, a lower electrode on the storage pad and including a trench defined by a bottom and sidewalls of the lower electrode, a lower support pattern including a first portion in the trench and a second portion on an upper surface of the lower electrode, an upper support pattern on an upper surface of the lower support pattern, a capacitor dielectric film on the lower electrode, the lower support pattern, and the upper support pattern, and an upper electrode on the capacitor dielectric film.

### CROSS-REFERENCE TO RELATED APPLICATION

This application claims priority from Korean Patent Application No. 10-2023-0141822 filed on Oct. 23, 2023, in the Korean Intellectual Property Office, and all the benefits accruing therefrom under 35 U.S.C. § 119, the contents of which in its entirety are herein incorporated by reference.

### BACKGROUND

The present disclosure relates generally to a semiconductor memory device and a method for manufacturing the same.

Recently, as semiconductor memory devices have become larger in capacity and more highly integrated, design rules are continuously decreasing. This trend is also occurring in dynamic random access memory (DRAM) as one of semiconductor memory devices. In order for the DRAM device to operate, each cell requires a certain level or greater of capacitance.

To increase the capacitance, a scheme of increasing an aspect ratio of a lower electrode of a capacitor or increasing a size of a contact area between the lower electrode and a dielectric film of the capacitor are being studied. When increasing the aspect ratio of the lower electrode, of the capacitor, a supporter that may support the lower electrode of the capacitor is used to prevent the lower electrode from tilting or being bent.

### SUMMARY

A technical purpose that the present disclosure aims to achieve is to provide a semiconductor memory device with improved product reliability.

Another technical purpose that the present disclosure seeks to achieve is to provide a method for manufacturing a semiconductor memory device with improved product reliability.

Purposes according to the present disclosure are not limited to the above-mentioned purposes. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means shown in the claims or combinations thereof.

According to an embodiment of the present disclosure, a semiconductor memory device includes a storage pad on a substrate; a lower electrode on the storage pad and including a trench; a lower support pattern including a first portion at least partially filling the trench, and a second portion on an upper surface of the lower electrode; an upper support pattern on an upper surface of the lower support pattern; a capacitor dielectric film on the lower electrode, the lower support pattern, and the upper support pattern; and an upper electrode on the capacitor dielectric film.

According to an embodiment of the present disclosure, a semiconductor memory device includes a storage pad on a substrate; a lower electrode on the storage pad and including a trench; a lower support pattern at least partially filling the trench and extending along an upper surface of the lower electrode and along an outer wall of a top portion of the lower electrode; a capacitor dielectric film on the lower electrode and the lower support pattern; and an upper electrode on the capacitor dielectric film.

According to an embodiment of the present disclosure, a method for manufacturing a semiconductor memory device includes sequentially forming an etch stop film and a mold film on a substrate; forming a lower electrode hole (i.e., opening) extending through the etch stop film and the mold film; forming a lower electrode extending along the lower electrode hole and including a trench; forming a lower support pattern at least partially filling the trench and extending along an upper surface of the mold film; forming an upper support pattern on the lower support pattern; removing the mold film to expose a portion of the lower electrode, a portion of the lower support pattern, and a portion of the upper support pattern; forming a capacitor dielectric film extending along the exposed portion of the lower electrode, the exposed portion of the lower support pattern, and the exposed portion of the upper support pattern; and forming an upper electrode on the capacitor dielectric film.

### BRIEF DESCRIPTION OF DRAWINGS

The above and other aspects and features of the present disclosure will become more apparent by describing in detail illustrative embodiments thereof with reference to the attached drawings, wherein like reference numerals (when used) indicate corresponding elements throughout the several views, and in which:

FIG. 1 is a schematic plan view for illustrating a semiconductor memory device according to some embodiments;

FIG. 2 is an illustrative schematic cross-sectional view of the semiconductor memory device shown in FIG. 1, taken along a line I-I of FIG. 1;

FIG. 3 to FIG. 10 are schematic cross-sectional views depicting intermediate structures corresponding to intermediate steps of an example method for manufacturing a semiconductor memory device according to some embodiments;

FIG. 11 is a schematic cross-sectional diagram for illustrating a semiconductor memory device according to some embodiments;

FIG. 12 and FIG. 13 are schematic cross-sectional diagrams of intermediate structures corresponding to intermediate steps of an example method for manufacturing a semiconductor memory device according to some embodiments;

FIG. 14 is a schematic cross-sectional diagram for illustrating a semiconductor memory device according to some embodiments;

FIG. 15 is a schematic cross-sectional diagram of an intermediate structure corresponding to an intermediate step of an example method for manufacturing a semiconductor memory device according to some embodiments;

FIG. 16 to FIG. 18 are schematic diagrams for illustrating a semiconductor memory device according to some embodiments;

FIG. 19 is a schematic layout diagram (i.e., top plan view) for illustrating a semiconductor memory device according to some embodiments;

FIG. 20 is a schematic perspective view for illustrating a semiconductor memory device according to some embodiments;

FIG. 21 is a schematic cross-sectional view of the semiconductor memory device shown in FIG. 19, taken along a line C-C and a line D-D in FIG. 19;

FIG. 22 is a schematic layout diagram for illustrating a semiconductor memory device according to some embodiments; and

FIG. 23 is a schematic perspective view for illustrating a semiconductor memory device according to some embodiments.

### DETAILED DESCRIPTION

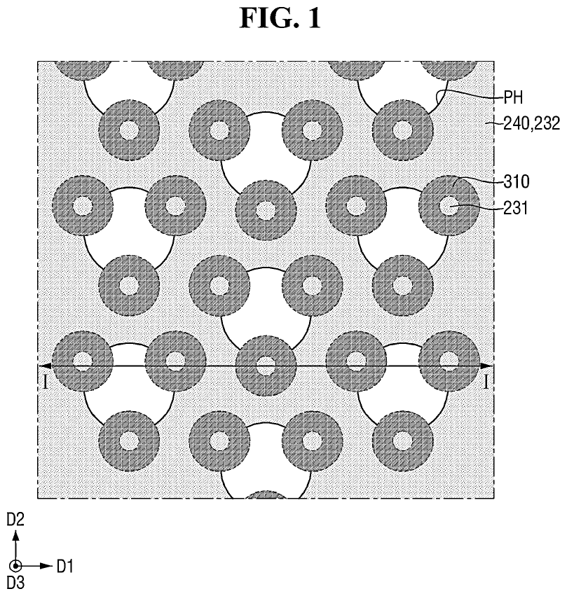

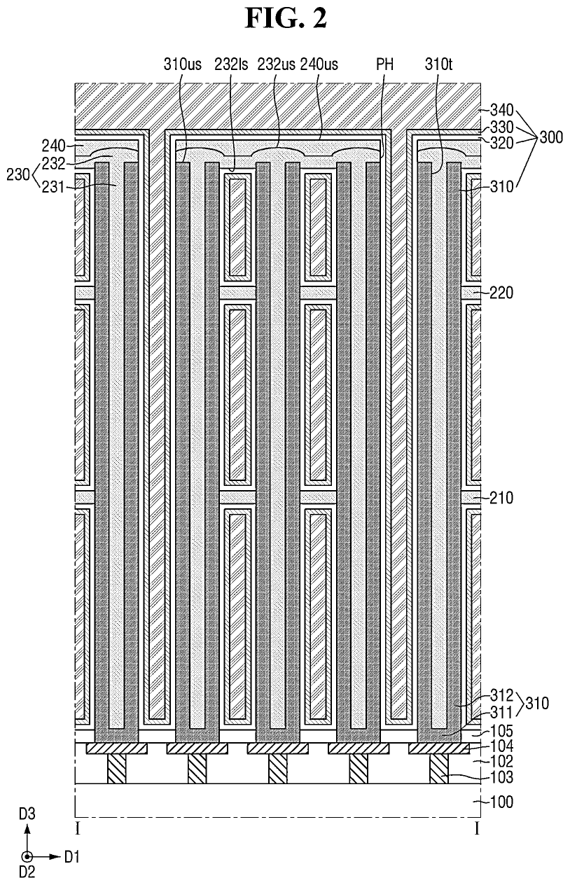

FIG. 1 is a schematic plan view for illustrating an example semiconductor memory device according to some embodiments. FIG. 2 is an illustrative schematic cross-sectional view of the semiconductor memory device shown in FIG. 1, taken along line I-I of FIG. 1.

Referring to FIG. 1 and FIG. 2, a semiconductor memory device according to some embodiments includes a substrate 100, a storage pad 104, and a capacitor structure 300.

The substrate 100 may comprise bulk silicon or SOI (silicon-on-insulator). Alternatively, the substrate 100 may be a silicon substrate, or may include a material other than silicon, such as silicon germanium, SGOI (silicon germanium on insulator), indium antimonide, lead telluride compound, indium arsenide, indium phosphide, gallium arsenide, or gallium antimonide. However, the present disclosure is not limited thereto. In the following description, an example in which the substrate 100 is embodied as a silicon substrate is described.

An interlayer insulating film 102 is disposed on the substrate 100. For example, the interlayer insulating film 102 may include at least one of silicon oxide, silicon nitride, silicon oxynitride (SiON), silicon oxycarbonitride (SiOCN), and combinations thereof, although embodiments are not limited thereto. The interlayer insulating film 102 may be a single layer or a multilayer.

A storage contact 103 and a storage pad 104 are disposed on the substrate 100. The storage contact 103 and the storage pad 104 are disposed in the interlayer insulating film 102. The storage pad 104 is disposed on the storage contact 103. The storage pad 104 may be connected to the substrate 100 via the storage contact 103. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The storage pad 104 may be electrically connected to a conductive area formed on or in the substrate 100.

An etch stop film 105 may be disposed on the interlayer insulating film 102. The etch stop film 105 may not cover at least a portion of an upper surface of the storage pad 104 so as to be exposed. The term “cover” (or “covering,” “covers,” or like terms), as may be used herein, is intended to broadly refer to an element, structure or layer that is on or over another element, structure or layer, either directly or with one or more other intervening elements, structures or layers therebetween. Furthermore, the term “exposed” (or “exposes,” or like terms) may be used herein to describe relationships between elements and/or with reference to intermediate processes in fabricating a semiconductor memory device, but may not require exposure of a particular element in the completed device. Likewise, the term “not exposed” may be used to described relationships between elements and/or with reference to intermediate processes in fabricating a semiconductor memory device, but may not require a particular element to be unexposed in the completed device. The etch stop film 105 may include at least one of, for example, silicon nitride (SiN), silicon carbonitride (SiCN), silicon boronitride (SiBN), silicon carbonate (SiCO), silicon oxynitride (SiON), silicon oxide (SiO), or silicon oxycarbonitride (SiOCN). For example, silicon carbonate (SiCO) refers to including silicon (Si), carbon (C), and oxygen (O), but does not mean a ratio between contents of silicon (Si), carbon (C), and oxygen (O).

A capacitor structure 300 may be disposed on the storage pad 104. The capacitor structure 300 may include a lower electrode 310, a capacitor dielectric film 320, an upper electrode 330, and an upper plate electrode 340.

The lower electrode 310 may be disposed on the storage pad 104. The lower electrode 310 may extend in a vertical direction D3, perpendicular to an upper surface of the substrate 100, through the etch stop film 105 so as to be electrically connected to the storage pad 104.

The lower electrodes 310 may be arranged in a honeycomb structure. That is, the lower electrodes 310 may be respectively positioned at a center and vertexes of a hexagon. The lower electrodes 310 may be arranged so as to be spaced from each other in a first direction D1 by an equal spacing. The lower electrodes 310 may be repeatedly arranged along each of the first direction D1 and a second direction D2. Hereinafter, the first direction D1 and the second direction D2 are directions parallel to the upper surface of the substrate 100. The second direction D2 is a direction perpendicular to the first direction D1. A third direction D3 is a vertical direction perpendicular to the upper surface of the substrate 100. The upper surface, the lower surface, an upper portion and a lower portion are defined based on the third direction D3.

The lower electrode 310 extends in an elongate (i.e., longitudinal) manner in the third direction D3. The lower electrode 310 may have a cylindrical shape, although embodiments are not limited thereto. The lower electrode 310 includes a bottom portion 311 extending horizontally along an upper surface of the storage pad 104, and a vertical portion 312 extending from the bottom portion 311 in the third direction D3. A length of the vertical portion 312 in a direction in which the vertical portion 312 extends, that is, the third direction D3, may be larger than a length of the bottom portion 311 in a direction in which the bottom portion 311 extends; that is, the lower electrode 310 may be formed as a high aspect ratio structure. A trench 310t may be defined by the bottom portion 311 and the vertical portion 312 of the lower electrode 310. The trench 310t extends from an upper surface 310us of the lower electrode 310 toward the substrate 100. The upper surface 310us of the lower electrode 310 may have a donut shape when viewed in plan view. The upper surface 310us of the lower electrode 310 is an upper surface of the vertical portion 312.

In some embodiments, for example, a thickness of a portion of the lower electrode 310 defining a bottom surface of the trench 310t (e.g., a thickness in the third direction D3 of the bottom portion 311) may be substantially the same as a thickness of a portion of the lower electrode 310 that defines a sidewall of the trench 310t (e.g., a width of the vertical portion 312 in the first direction D1). The thickness of the portion of the lower electrode 310 that defines the sidewall of the trench 310t (e.g., the width of the vertical portion 312 in the first direction D1) may be substantially constant along the third direction D3.

In some embodiments, a width of the trench 310t in a direction parallel to the upper surface of substrate 100 (e.g., the first direction D1 or the second direction D2) may be constant or decrease as the trench 310t extends in the third direction D3 toward the substrate 100. The thickness of the portion of the lower electrode 310 that defines the sidewall of the trench 310t (e.g., the width of the vertical portion 312 in the first direction D1) may be constant or decrease as the vertical portion 312 extends toward the substrate 100.

The lower electrode 310 may include, for example, a doped semiconductor material, a conductive metal nitride (e.g., titanium nitride, tantalum nitride, niobium nitride or tungsten nitride, etc.), a metal (e.g., ruthenium, iridium, titanium, etc. or tantalum, etc.), or a conductive metal oxide (e.g., iridium oxide or niobium oxide, etc.). However, the present disclosure is not limited thereto. In the semiconductor memory device according to some embodiments, the lower electrode 310 may include titanium nitride (TiN). Alternatively, in the semiconductor memory device according to some embodiments, the lower electrode 310 may include niobium nitride (NbN).

A first support pattern 210, a second support pattern 220, and a lower support pattern 230 and an upper support pattern 240 may be sequentially disposed (e.g., stacked in the third direction D3) on the etch stop film 105. The first support pattern 210 may be spaced from the etch stop film 105 in the third direction D3. The second support pattern 220 may be spaced from the first support pattern 210 in the third direction D3. The lower support pattern 230 may be spaced from the second support pattern 220 in the third direction D3. The upper support pattern 240 may be disposed on the lower support pattern 230.

The number of support patterns 210, 220, 230, and 240 supporting the lower electrode 310 may vary. For example, only the lower support pattern 230 and the upper support pattern 240 may support the lower electrode 310. A relationship between a thickness in the third direction D3 of the first support pattern 210, a thickness in the third direction D3 of the second support pattern 220, a thickness in the third direction D3 of the lower support pattern 230, and the thickness in the third direction D3 of the upper support pattern 240 may vary. A relationship between a spacing between the etch stop film 105 and the first support pattern 210, a spacing between the first support pattern 210 and the second support pattern 220, and a spacing between the second support pattern 220 and the lower support pattern 230 may vary.

The first support pattern 210, the second support pattern 220, the lower support pattern 230, and the upper support pattern 240 may be sequentially spaced apart from each other and may be disposed on a sidewall of the lower electrode 310. Each of the first support pattern 210, the second support pattern 220, the lower support pattern 230, and the upper support pattern 240 may be in contact with a portion of the side wall of the lower electrode 310. The first support pattern 210, the second support pattern 220, and the lower support pattern 230 and upper support pattern 240 may connect adjacent lower electrodes 310 to each other. In the drawing, three lower electrodes 310 are shown as being connected to each other via the first support pattern 210, the second support pattern 220, the lower support pattern 230, and the upper support pattern 240. However, the present disclosure is not limited thereto.

The lower support pattern 230 includes a first portion 231 and a second portion 232. The lower support pattern 230 has an integrated structure. That is, the first portion 231 and the second portion 232 are integrated with each other so as to directly contact each other without an internal boundary therebetween (i.e., the lower support pattern 230 is formed as a homogeneous structure comprising the first and second portions 231, 232).

The first portion 231 fills the trench 310t of the lower electrode 310. For example, the first portion 231 may fill an entirety of the trench 310t of the lower electrode 310. The term “fills” (or “filling,” “filled,” or like terms), as may be used herein, is intended to refer broadly to either completely filling a defined space (e.g., the trench 310t) or partially filling the defined space; that is, the defined space need not be entirely filled but may, for example, be partially filled or have voids or other spaces throughout.

The second portion 232 is connected to the first portion 231. The second portion 232 is disposed on an upper surface 310us of the lower electrode 310. The second portion 232 extends along the upper surface 310us of the lower electrode 310. The second portion 232 may contact the upper surface 310us of the lower electrode 310. The second portion 232 extends in a direction parallel to the upper surface of the substrate 100 (e.g., the first direction D1 or the second direction D2).

An upper surface 232us of the second portion 232 may include a portion that is convex in a direction (i.e., the third direction D3) opposite to a direction toward the substrate 100 (i.e., facing away from the substrate 100). For example, the upper surface 232us of the second portion 232 which overlaps the lower electrode 310 in the third direction D3 may be convex in the third direction D3. The term “overlaps” (or “overlapping,” or like terms), as may be used herein, is intended to broadly refer to a first element that intersects with at least a portion of a second element in the vertical direction (i.e., third direction D3), but does not require that the first and second elements be completely aligned with one another in a horizontal plane (i.e., in the first direction D1 or the second direction D2).

In some embodiments, the second portion 232 extends along an outer wall of a top portion of the lower electrode 310. The second portion 232 may contact the outer wall of a top portion of the lower electrode 310. The second portion 232 surrounds the top portion of the lower electrode 310. A lowest surface 232ls of the second portion 232 is positioned at a lower vertical level than that of the upper surface 310us of the lower electrode 310, relative to the upper surface of the substrate 100 as a reference surface. A portion of the lower surface 232ls of the second portion 232 which does not overlap the lower electrode 310 in the third direction D3 is positioned at a lower vertical level than that of the upper surface 310us of the lower electrode 310, relative to the upper surface of the substrate as a reference surface.

The upper support pattern 240 is disposed on an upper surface of the lower support pattern 230 (i.e., an upper surface 232us of the second portion 232). The upper support pattern 240 contacts the upper surface of the lower support pattern 230. The upper support pattern 240 extends along the lower support pattern 230, and thus a lower surface of the upper support pattern 240 may be non-planar. An upper surface 240us of the upper support pattern 240 may be flat (i.e., planar).

Each of the first support pattern 210, the second support pattern 220, the lower support pattern 230, and the upper support pattern 240 includes a material different from that of the lower electrode 310. Each of the first support pattern 210, the second support pattern 220, the lower support pattern 230, and the upper support pattern 240 may include at least one of, for example, silicon nitride (SiN), silicon carbonitride (SiCN), silicon boron nitride (SiBN), silicon carbonate (SiCO), silicon oxynitride (SiON), silicon oxide (SiO), and silicon oxycarbonitride (SiOCN).

In some embodiments, the lower support pattern 230 and the upper support pattern 240 may include the same material. For example, each of the lower support pattern 230 and the upper support pattern 240 may include silicon carbon nitride (SiCN). In some further embodiments, the lower support pattern 230 and upper support pattern 240 may include different materials.

A through-hole PH may be defined between the lower electrodes 310 that are adjacent to each other. The through holes PH may be spaced apart from each other in the first direction D1 and the second direction D2. For example, in a plan view (FIG. 1), the through-hole PH may be formed in a circle shape and may be defined between three adjacent lower electrodes 310. A portion of a side surface of each of the three lower electrodes 310 may be exposed through the through-hole PH. However, the present disclosure is not limited thereto, and the through-hole PH may be defined between a plurality of lower electrodes 310 and may be formed in various shapes. The through-hole PH may extend through the first support pattern 210, the second support pattern 220, the lower support pattern 230, and the upper support pattern 240. The through-hole PH may expose the etch stop film 105.

The capacitor dielectric film 320 may be disposed on the lower electrode 310, the first support pattern 210, the second support pattern 220, the lower support pattern 230, and the upper support pattern 240. The capacitor dielectric film 320 may extend along a profile of the lower electrode 310, the upper surface and the lower surface of the first support pattern 210, the upper surface and the lower surface of the second support pattern 220, the lower surface and a side surface of the lower support pattern 230, and the upper surface and a side surface of the upper support pattern 240. The capacitor dielectric film 320 may fill at least a portion of the through-hole PH.

The capacitor dielectric film 320 may include, for example, a high dielectric constant (high-k) material including silicon oxide, silicon nitride, silicon oxynitride, and metal, although embodiments are not limited thereto. The capacitor dielectric film 320 is shown as being formed as a single film. However, this is only for convenience of illustration and the present disclosure is not limited thereto.

The upper electrode 330 may be disposed on the capacitor dielectric film 320. The upper electrode 330 may extend along a profile of the capacitor dielectric film 320. The upper plate electrode 340 may be disposed on the upper electrode 330. The upper electrode 330 may be disposed between the capacitor dielectric film 320 and the upper plate electrode 340. The upper electrode 330 and the upper plate electrode 340 may fill the through-hole PH, a space between the etch stop film 105 and the first support pattern 210, a space between the first support pattern 210 and the second support pattern 220, and a space between the second support pattern 220 and the lower support pattern 230.

The upper electrode 330 may include, for example, a doped semiconductor material, a conductive metal nitride (e.g., titanium nitride, tantalum nitride, niobium nitride or tungsten nitride, etc.), a metal (e.g., ruthenium, iridium, titanium, etc. or tantalum, etc.), or a conductive metal oxide (e.g., iridium oxide or niobium oxide, etc.). However, the present disclosure is not limited thereto.

The upper plate electrode 340 may include, for example, at least one of an elemental semiconductor material film or a compound semiconductor material film. The upper plate electrode 340 may contain doped n-type impurities or p-type impurities.

In the semiconductor memory device according to some embodiments, the lower support pattern 230 fills an inner space defined by the lower electrode 310, that is, the trench 310t. Further, in the semiconductor memory device according to some embodiments, the lower support pattern 230 surrounds the top portion of the lower electrode 310. The term “surrounds” (or “surround,” “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. Therefore, the lower electrode 310 may be prevented from tilting and being bent. Accordingly, the reliability of the semiconductor memory device may be improved.

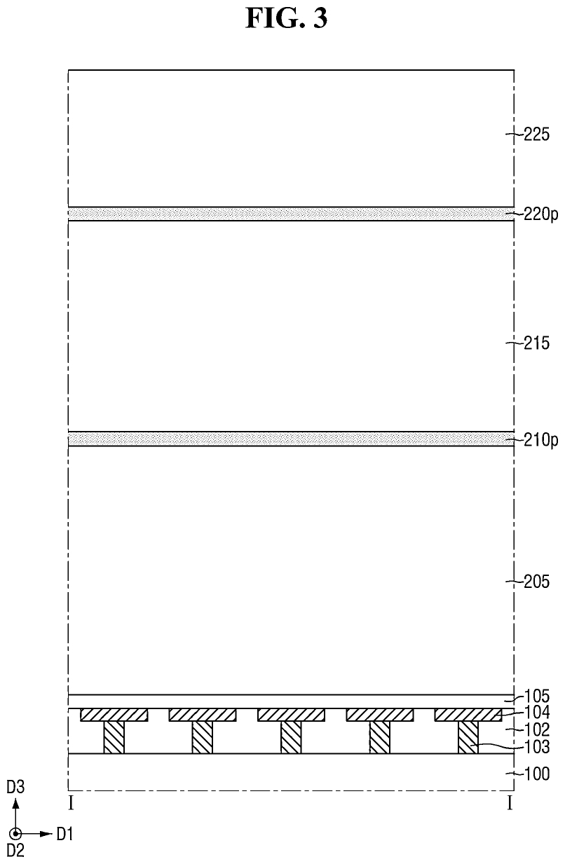

FIG. 3 to FIG. 10 are schematic cross-sectional views depicting intermediate structures corresponding to intermediate steps of an example method for manufacturing a semiconductor memory device, according to some embodiments. For reference, FIG. 3 to FIG. 10 are cross-sectional views of the illustrative semiconductor memory device shown in FIG. 1, taken along line I-I in FIG. 1. For convenience of description, following descriptions are mainly based on differences thereof from the description set forth above in connection with FIG. 1 and FIG. 2.

Referring to FIG. 3, the storage contact 103 and the storage pad 104 may be formed in the interlayer insulating film 102 on the substrate 100. The etch stop film 105 may be formed on the interlayer insulating film 102 and the storage pad 104.

Subsequently, on the etch stop film 105, a first mold film 205, a first support film 210p, a second mold film 215, a second support film 220p, and a third mold film 225 are formed in this order (i.e., sequentially formed). The first support film 210p may include a material having etch selectivity with respect to that of each of the first mold film 205 and the second mold film 215. The second support film 220p may include a material having etch selectivity with respect to that of each of the second mold film 215 and the third mold film 225. Each of the first to third mold films 205, 215, and 225 may have a single film structure or a multi-layer structure including a plurality of different films.

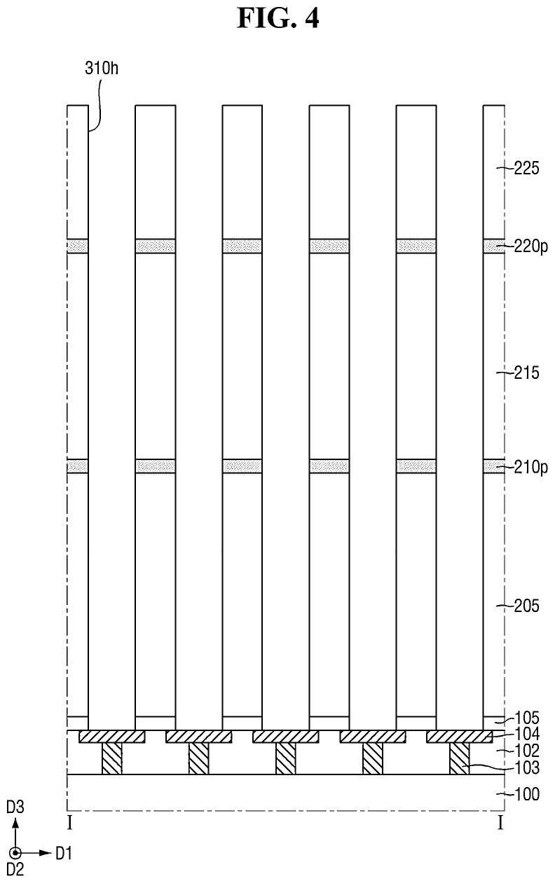

Referring to FIG. 4, a lower electrode hole 310h extending in the third direction D3 through the etch stop film 105, the first mold film 205, the first support film 210p, the second mold film 215, the second support film 220p, and the third mold film 225 may be formed. A portion of an upper surface of the storage pad 104 may be exposed through the lower electrode hole 310h. In some embodiments, the lower electrode hole 310h may have a constant horizontal width. In some further embodiments, the lower electrode hole 310h may have a tapered shape in which the horizontal width is smaller as the lower electrode hole 310h extends from a top to a bottom thereof.

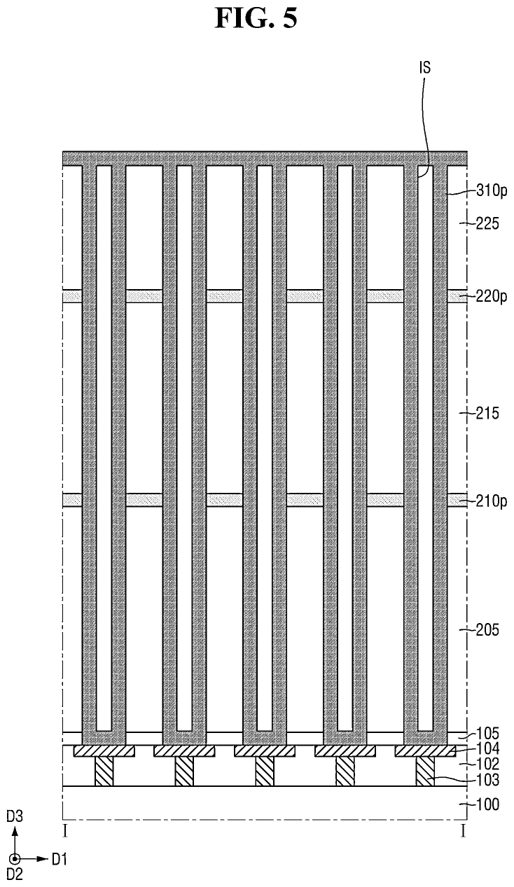

Referring to FIG. 5, a lower electrode film 310p may be formed on sidewalls and a bottom of the lower electrode hole 310h (see FIG. 4). The lower electrode film 310p may be formed on the third mold film 225, and may at least partially fill the lower electrode hole 310h. The lower electrode film 310p may cover the portion of the upper surface of the storage pad 104 exposed through the lower electrode hole 310h and may cover the third mold film 225. For example, the lower electrode film 310p may be formed by a process such as chemical vapor deposition (CVD), atomic layer deposition (ALD), or plasma enhanced ALD (PEALD).

The lower electrode film 310p may be formed along the lower electrode hole 310h and an upper surface of the third mold film 225. The lower electrode film 310p may be formed to fill the lower electrode hole 310h. The lower electrode film 310p may be formed along a profile of the lower electrode hole 310h. As deposition of the lower electrode film 310p progresses, the lower electrode film 310p may be formed on an inner wall defining the lower electrode hole 310h so as to fill the lower electrode hole 310h. At this time, an empty space IS may be formed inside the lower electrode film 310p. The empty space IS may define an inner wall of the lower electrode film 310p. The lower electrode film 310p may fill a portion of the lower electrode hole 310h.

In some embodiments, a width of the empty space IS in a direction parallel to the upper surface of substrate 100 (e.g., the first direction D1 or the second direction D2) may be substantially constant along the third direction D3.

For example, a thickness, in the third direction D3, of a portion of the lower electrode film 310p defining a bottom surface of the empty space IS may be substantially the same as a thickness, in the first direction D1, of a portion of the lower electrode film 310p defining a sidewall of the empty space IS.

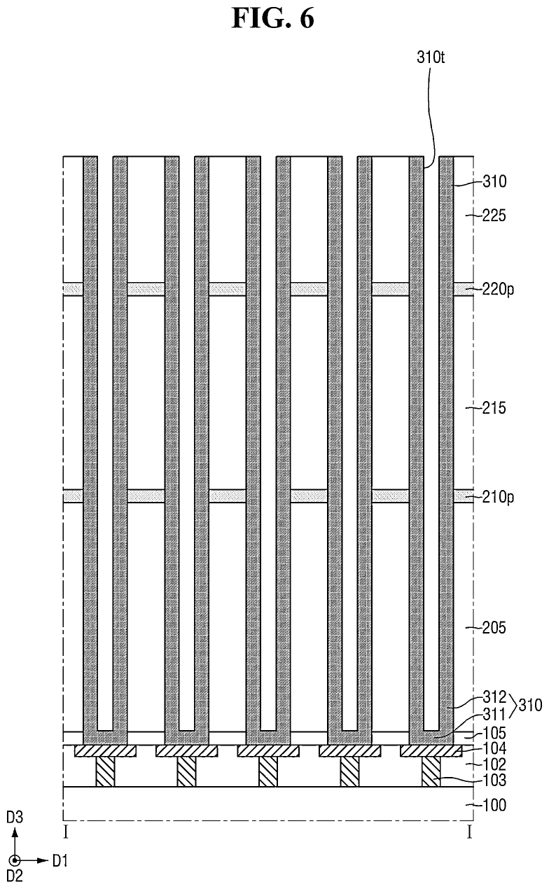

Referring to FIG. 5 and FIG. 6, a top portion of the lower electrode film 310p may be removed to form the lower electrode 310. For example, the top portion of the lower electrode film 310p may be removed by an etch-back process.

As the top portion of the lower electrode film 310p is removed, the empty space IS may be exposed, such that the trench 310t may be formed. The trench 310t may extend in the third direction D3 from the upper surface 310us (see FIG. 2) of the lower electrode 310 toward the substrate 100.

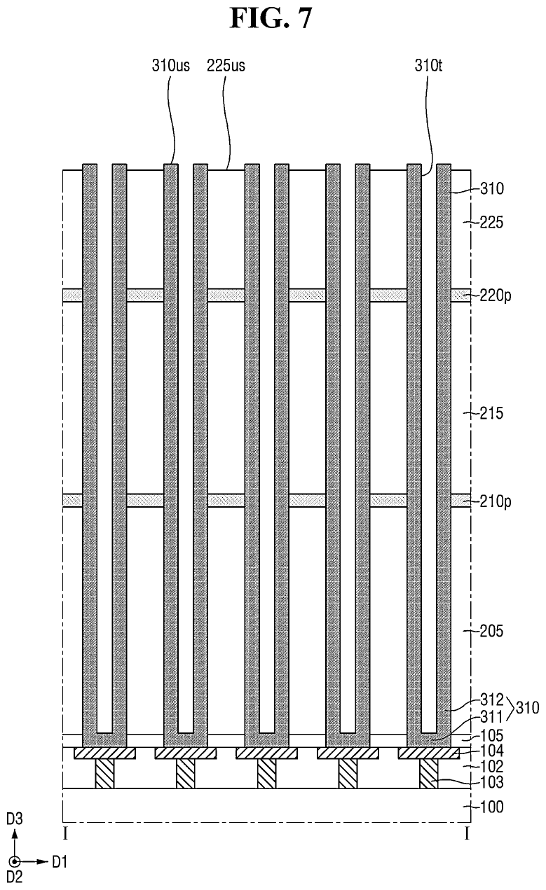

Referring to FIG. 7, a top portion of the third mold film 225 may be removed. Accordingly, the top portion of the lower electrode 310 may be not covered with the third mold film 225 so as to be exposed. The upper surface 310us of the lower electrode 310 may be positioned at a higher level than that of the upper surface 225us of the third mold film 225, relative to the upper surface of the substrate 100 as a reference surface.

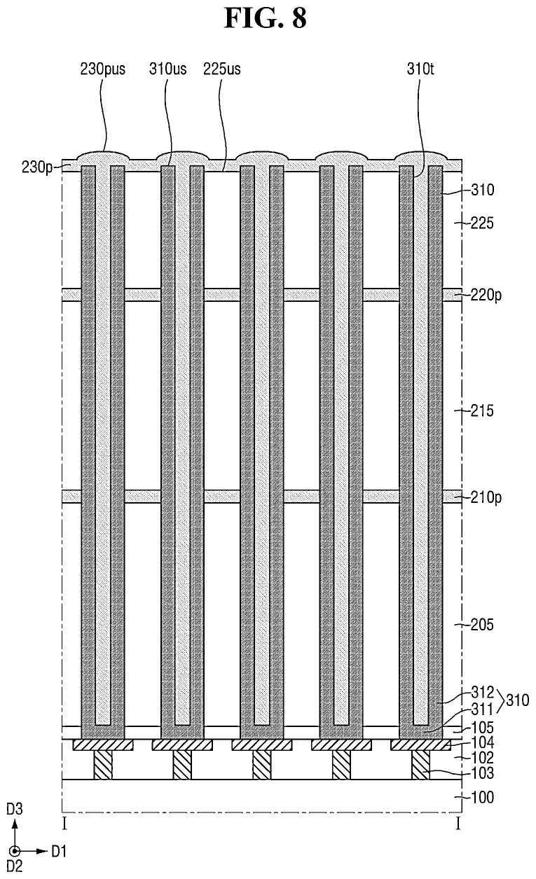

Referring to FIG. 8, a lower support film 230p may be formed so as to fill the trench 310t and cover the third mold film 225 and the top portion of the lower electrode 310. The lower support film 230p may cover the upper surface 225us of the third mold film 225. Due to the top portion of the lower electrode 310 not covered with the third mold film 225 so as to be exposed, an upper surface 230pus of the lower support film 230p covering (i.e., overlapping) the lower electrode 310 may be convex, and therefore non-planar. The upper surface 230pus of the lower support film 230p may be later converted to the upper surface 230us (in FIG. 2) of the lower support pattern 230 in FIG. 2.

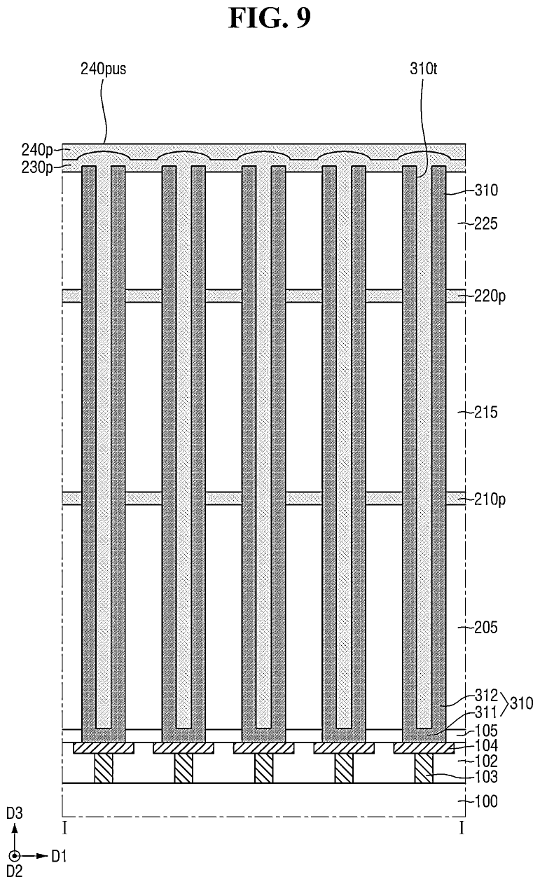

Referring to FIG. 9, an upper support film 240p may be formed on the lower support film 230p. The upper support film 240p may cover the lower support film 230p. An upper surface 240pus of the upper support film 240p may be flat, despite a lower surface of the upper support film 240p being non-planar to correspond to a contour of the upper surface 230pus of the lower support film 230p. The upper surface 240pus of the upper support film 240p may be later converted to the upper surface 240us (in FIG. 2) of the upper support pattern 240 in FIG. 2.

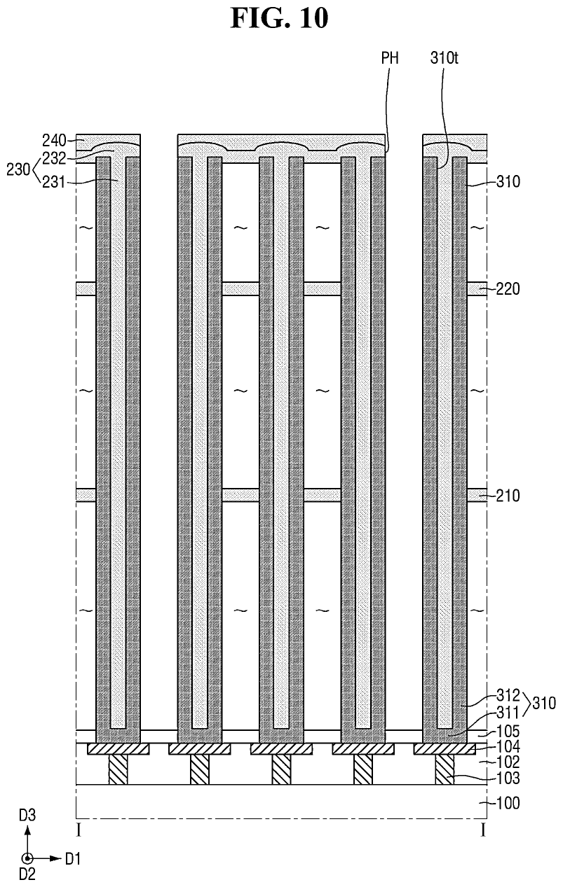

Referring to FIG. 9 and FIG. 10, the through-hole PH extending through the first mold film 205, the first support film 210p, the second mold film 215, the second support film 220p, the third mold film 225, the lower support film 230p and the upper support film 240p may be formed. Outer walls of some of the lower electrodes 310, adjacent to each other in the first direction D1, and a portion of the upper surface of the etch stop film 105 may be exposed through the through-hole PH. Accordingly, the first support pattern 210, the second support pattern 220, the lower support pattern 230, and the upper support pattern 240 may be formed. Portions of the first support film 210p, the second support film 220p, the lower support film 230p, and the upper support film 240p which have not been etched but remain may respectively become the first support pattern 210, the second support pattern 220, the lower support pattern 230, and the upper support pattern 240.

The first to third mold films 205, 215, and 225 exposed through the through-hole PH may be removed. For example, the first to third mold films 205, 215, and 225 may be removed by a wet etching process. Accordingly, the lower electrode 310, the first support pattern 210, the second support pattern 220, the lower support pattern 230, and the upper support pattern 240 may be exposed.

Referring to FIG. 2, the capacitor dielectric film 320 extending along the lower electrode 310, the first support pattern 210, the second support pattern 220, the lower support pattern 230, and the upper support pattern 240 as exposed may be formed. The capacitor dielectric film 320 may be formed on the upper surface and the lower surface of the first support pattern 210, the upper surface and the lower surface of the second support pattern 220, the side surface of the lower support pattern 230, the upper surface and the side surface of the and upper support pattern 240, and the upper surface of the etch stop film 105.

The upper electrode 330 may be formed on the capacitor dielectric film 320. An upper plate electrode 340 may be formed on the upper electrode 330. While the upper plate electrode 340 is being formed, a portion of the upper electrode 330 may be patterned to correspond to a size of the upper plate electrode 340. The upper electrode 330 and the upper plate electrode 340 may fill the space between the etch stop film 105 and the first support pattern 210, the space between the first support pattern 210 and the second support pattern 220, the space between the second support pattern 220 and the lower support pattern 230, and the through-hole PH.

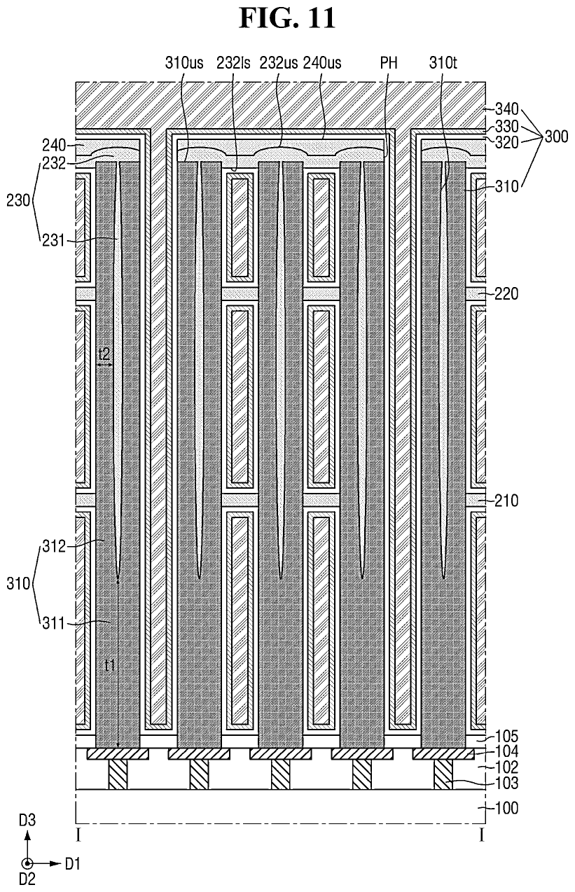

FIG. 11 is a schematic diagram for illustrating a semiconductor memory device according to some embodiments. For reference, FIG. 11 is a cross-sectional view of the semiconductor memory device shown in FIG. 1, taken along line I-I in FIG. 1. For convenience of description, the following descriptions are mainly based on differences thereof from the descriptions as set forth above using FIG. 1 and FIG. 2.

Referring to FIG. 11, in the semiconductor memory device according to some embodiments, a first thickness t1 of a portion of the lower electrode 310 defining the bottom surface of the trench 310t (for example, the thickness of the bottom portion 311 in the third direction D3 may be different from a second thickness t2 of a portion of the lower electrode 310 defining the sidewall of the trench 310t (for example, the width in the first direction D1 of the vertical portion 312). The first thickness t1 may be larger than the second thickness t2.

In some embodiments, the width of the trench 310t in a direction parallel to the upper surface of the substrate 100 (e.g., the first direction D1 or the second direction D2) may not be constant along the third direction D3. For example, the width of the trench 310t in the direction parallel to the upper surface of the substrate 100 may increase and then decrease as the trench 310t extends toward the substrate 100 in the third direction D3. The second thickness t2 of the portion of the lower electrode 310 defining the sidewall of the trench 310t (for example, the width in the first direction D1 of the vertical portion 312) may decrease and then increase as the vertical portion 312 extends toward the substrate 100.

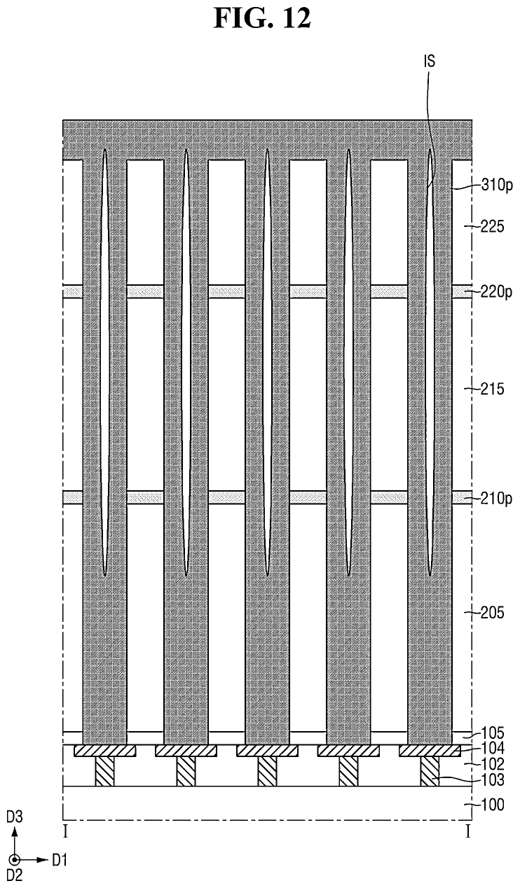

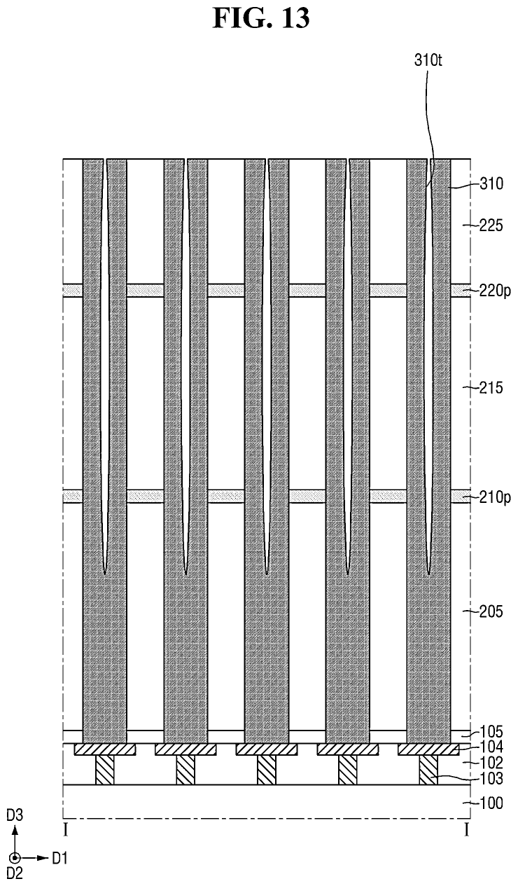

FIG. 12 and FIG. 13 are schematic diagrams of intermediate structures corresponding to intermediate steps of an example method for manufacturing a semiconductor memory device according to some embodiments. For reference, FIG. 12 and FIG. 13 are cross-sectional views of the semiconductor memory device shown in FIG. 1, taken along line I-I in FIG. 1, and FIG. 12 relates to a process after FIG. 4. For convenience of description, following descriptions are mainly based on differences thereof from the descriptions as set forth above using FIG. 1 to FIG. 11.

Referring to FIG. 12, a width of the empty space IS defined in the lower electrode film 310p in a direction parallel to the upper surface of the substrate 100 (e.g., the first direction D1 or the second direction D2) may not be substantially constant along the third direction D3. For example, the width of the empty space IS defined in the lower electrode film 310p in the direction parallel to the upper surface of the substrate 100 (e.g., the first direction D1 or the second direction D2) may increase and then decrease as the empty space IS extends toward the substrate 100.

For example, a thickness of a portion of the lower electrode film 310p defining the bottom surface of the empty space IS may be larger than a thickness of a portion of the lower electrode film 310p defining the sidewall of the empty space IS.

The lower electrode film 310p in FIG. 12 may be thicker than the lower electrode film 310p in FIG. 5. A shape of the empty space IS (e.g., having a non-uniform width in the direction parallel to the upper surface of the substrate 100) may be due to the fact that the lower electrode film 310p in FIG. 12 is thicker than the lower electrode film 310p in the semiconductor memory device of FIG. 5.

Referring to FIG. 12 and FIG. 13, a top portion of the lower electrode film 310p may be removed to form the lower electrode 310. As the top portion of the lower electrode film 310p is removed, the empty space IS may be exposed to form the trench 310t.

Subsequently, a manufacturing process of FIG. 6 to FIG. 13 may be performed. Accordingly, the semiconductor memory device as shown in FIG. 11 may be formed.

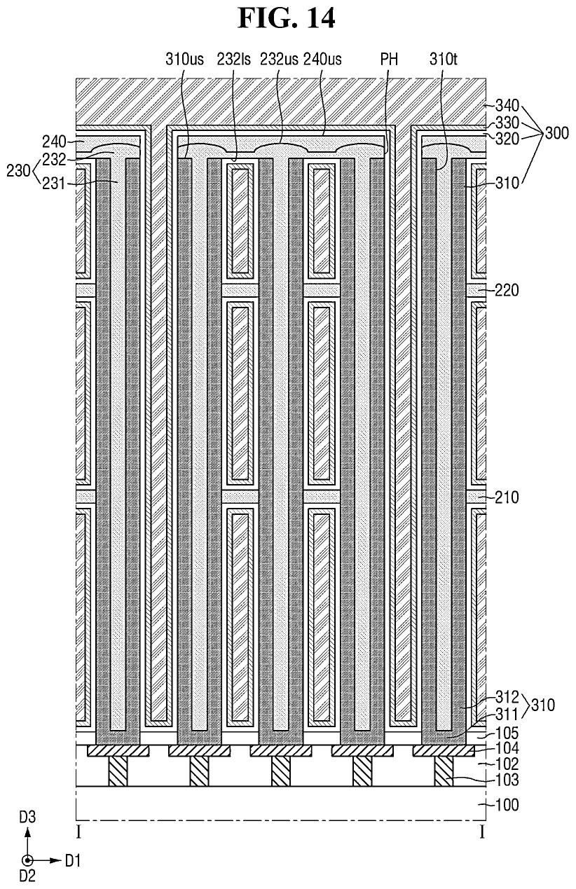

FIG. 14 is a schematic diagram for illustrating a semiconductor memory device according to some embodiments. For reference, FIG. 14 is a cross-sectional view of the semiconductor memory device shown in FIG. 1, taken along line I-I in FIG. 1. For convenience of description, following descriptions are mainly based on differences thereof from the descriptions as set forth above using FIG. 1 and FIG. 2.

Referring to FIG. 14, in the semiconductor memory device according to some embodiments, the lower surface 232ls of the second portion 232 may be coplanar (in the third direction D3) with the upper surface 310us of the lower electrode 310. The lower support pattern 230 may fill the trench 310t of the lower electrode 310 and extend along the upper surface 310us of the lower electrode 310. The lower support pattern 230 may not extend along the outer wall of the lower electrode 310.

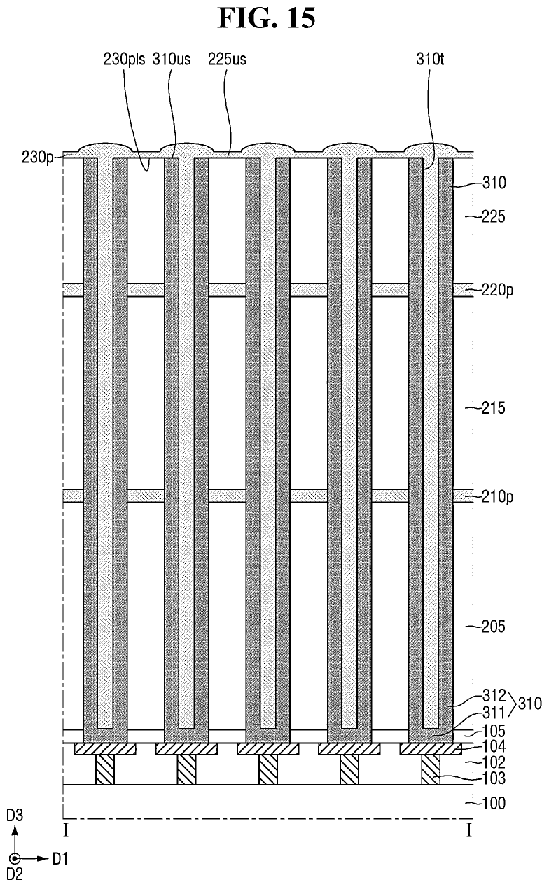

FIG. 15 is a schematic diagram of an intermediate structure corresponding to an intermediate step of a method for manufacturing a semiconductor memory device according to some embodiments. For reference, FIG. 15 is a cross-sectional view of the semiconductor memory device shown in FIG. 1, taken along line I-I in FIG. 1, and FIG. 15 relates to a process after FIG. 6. For convenience of description, following descriptions are mainly based on differences thereof from the descriptions as set forth above using FIG. 1 to FIG. 10 and FIG. 14.

Referring to FIG. 15, the lower support film 230p may be formed without the manufacturing process in FIG. 7. The upper surface 310us of the lower electrode 310 may be coplanar with the upper surface 225us of the third mold film 225. The lower support film 230p may cover the lower electrode 310 and the third mold film 225. A lower surface 230pls of the lower support film 230p may be coplanar with the upper surface 310us of the lower electrode 310. The lower surface 230pls of the lower support film 230p may be later converted to the lower surface 232ls (in FIG. 14) of the lower support pattern 230 (in FIG. 14).

Subsequently, the manufacturing process of FIG. 9 to FIG. 13 may be performed. Accordingly, the semiconductor memory device as shown in FIG. 14 may be formed.

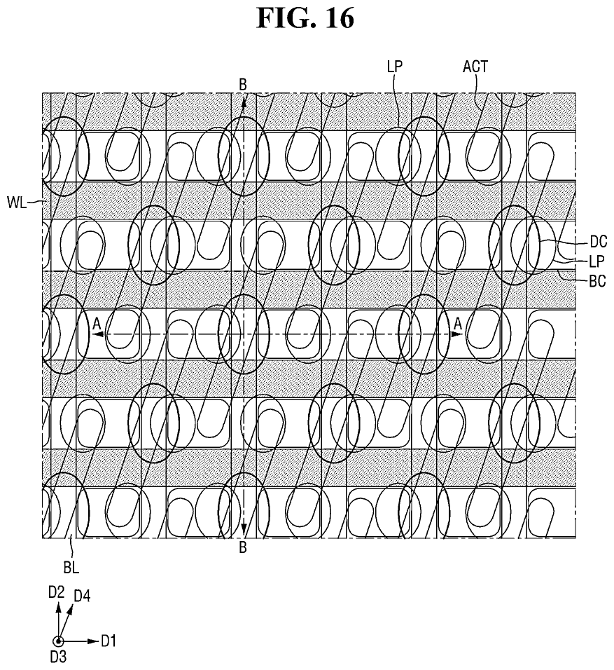

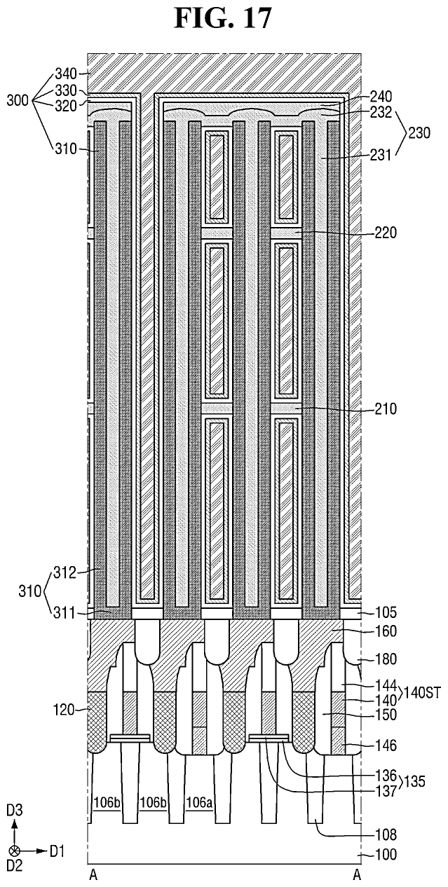

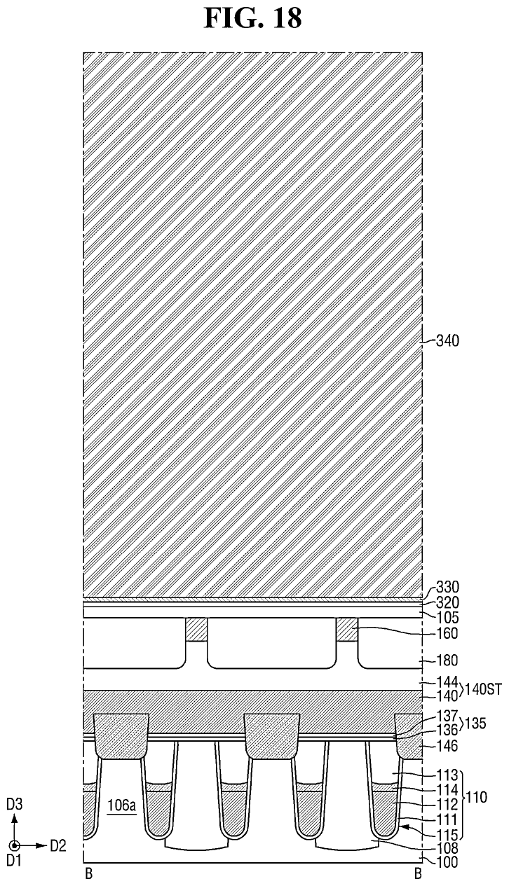

FIG. 16 to FIG. 18 are schematic diagrams for illustrating a semiconductor memory device according to some embodiments. For reference, FIG. 16 is a schematic layout (i.e., top plan view) for illustrating a semiconductor memory device according to some embodiments. FIG. 17 is a cross-sectional view of the semiconductor memory device shown in FIG. 16, taken along line A-A in FIG. 16. FIG. 18 is a cross-sectional view of the semiconductor memory device shown in FIG. 16, taken along line B-B in FIG. 16. For convenience of description, following descriptions are mainly based on differences thereof from the descriptions as set forth above using FIG. 1 to FIG. 15.

In the drawings of the semiconductor memory device according to some embodiments, an example in which the semiconductor memory device is embodied as DRAM (Dynamic Random Access Memory). However, the present disclosure is not limited thereto.

Referring to FIG. 16 to FIG. 18, the semiconductor memory device according to some embodiments may include a plurality of cell active areas ACT.

Each of the cell active areas ACT may be defined by a cell element isolation film 108 formed in the substrate 100. As the design rule of the semiconductor memory devices is reduced, the cell active area ACT may extend in a form of a bar extending in a diagonal line or an oblique line, as shown in FIG. 16. For example, the cell active area ACT may extend in a fourth direction D4. Hereinafter, the fourth direction D4 is a direction parallel to the upper surface of the substrate 100 and between the first direction D1 and the second direction D2 (i.e., intersecting the first direction D1 and second direction D2).

A plurality of gate electrodes extending in the first direction D1 and across the cell active area ACT may be arranged. The plurality of gate electrodes may extend parallel to each other. For example, the plurality of gate electrodes may act as a plurality of wordlines WL. The wordlines WL may be arranged so as to be spaced apart from each other by an equal spacing in the second direction D2. A width of the wordline WL or the spacing between the wordlines WL in the second direction D2 may be determined according to the design rule.

Each cell active area ACT may be divided into three portions by two wordlines WL extending in the first direction D1. The cell active area ACT may include a storage connection area 106b and a bit line connection area 106a. The bit line connection area 106a may be located in a middle portion of the cell active area ACT, and the storage connection area 106b may be located in an end of the cell active area ACT.

For example, the bit line connection area 106a may be an area connected to the bit line BL, and the storage connection area 106b may be an area connected to the capacitor structure 300. In other words, the bit line connection area 106a may act as a common drain area, and the storage connection area 106b may act as a source area. Each wordline WL and the bit line connection area 106a and the storage connection area 106b adjacent thereto may constitute a transistor.

A plurality of bit lines BL extending in the second direction D2 orthogonal to an extension direction of the wordline WL may be disposed on the wordline WL. The plurality of bit lines BL may extend parallel to each other. The bit lines BL may be spaced apart from each other in the first direction D1 by an equal spacing. The width of the bit line BL or the spacing between the bit lines BL in the first direction D1 may be determined according to the design rule.

The semiconductor memory device according to some embodiments may include various contact arrangements formed on the cell active area ACT. The various contact arrangements may include, for example, a direct contact DC, a buried contact BC, and a landing pad LP.

In this regard, the direct contact DC may refer to a contact that electrically connects the cell active area ACT to the bit line BL. The term “direct contact,” as may be used herein, is not intended to imply that there is necessarily a direct physical and/or electrical connection between the bit lines BL and corresponding cell active areas ACT; that is, intervening elements may be present between the bit lines BL and the cell active areas ACT. The buried contact BC may refer to a contact connecting the cell active area ACT to the lower electrode 310 of the capacitor structure 300. Due to the arrangement structure, a contact area size between the buried contact BC and the cell active area ACT may be small. Accordingly, the conductive landing pad LP may be introduced to increase a contact area size thereof with the cell active area ACT and to increase a contact area size thereof with the lower electrode 310.

The landing pad LP may be between the cell active area ACT and buried contact BC and may be between the buried contact BC and the lower electrode 310. In the semiconductor memory device according to some embodiments, a landing pad LP may be between the buried contact BC and the lower electrode 310. Increasing the contact area size via the introduction of the landing pad LP may allow a contact resistance between the cell active area ACT and the lower electrode 310 of the capacitor structure 300 to be reduced.

The direct contact DC may be connected to the bit line connection area 106a. The buried contact BC may be connected to the storage connection area 106b. As the buried contacts BC are respectively disposed on both opposing ends of the cell active area ACT, the landing pad LP may be adjacent to each of both opposing ends of the cell active area ACT and partially overlap the buried contact BC. In other words, the buried contact BC may be formed to overlap a portion of each of the cell active area ACT and the cell element isolation film 108 disposed between adjacent wordlines WL and between adjacent bit lines BL.

The wordline WL may have a buried structure in the substrate 100. The wordline WL may extend across a portion of the cell active area ACT between direct contacts DC or buried contacts BC. As shown, two wordlines WL may extend across one cell active area ACT. Because the cell active area ACT extends in the fourth direction D4, an angle defined between the wordline WL and the cell active area ACT may be smaller than 90 degrees.

The direct contacts DC may be symmetrically arranged. The buried contacts BC may be symmetrically arranged. Thus, the direct contacts DC may be arranged in a straight line along each of the first direction D1 and the second direction D2. The buried contacts BC may be arranged in a straight line along each of the first direction D1 and the second direction D2. Unlike the direct contacts DC and the buried contacts BC, the landing pads LP may be arranged in a zigzag manner in the second direction D2 in which the bit line BL extends. Further, the landing pads LP may be arranged in the first direction D1 in which the wordline WL extends so as to overlap the same side portions of corresponding bit lines BL, respectively. For example, the landing pads LP arranged in a first line in the first direction may overlap left side portions of corresponding bit lines BL, respectively. The landing pads LP arranged in a second line in the first direction may overlap right side portions of corresponding bit lines BL, respectively.

The semiconductor memory device according to some embodiments may include a plurality of cell gate structures 110, a plurality of bit line structures 140ST, a plurality of storage contacts 120, a plurality of storage pads 160, a plurality of bit line contacts 146, and the capacitor structure 300.

The cell element isolation film 108 may be formed in the substrate 100. The cell element isolation film 108 may have an STI (shallow trench isolation) structure with excellent element isolation ability. The cell element isolation film 108 may define the cell active area ACT in the memory cell area.

The cell active area ACT defined by the cell element isolation film 108 may have an elongate island shape including a minor axis and a major axis as shown in FIG. 16. The cell active area ACT may have an oblique shape to have an angle smaller than 90 degrees with respect to the wordline WL formed in the cell element isolation film 108. Further, the cell active area ACT may have an oblique shape to have an angle smaller than 90 degrees with respect to the bit line BL formed on the cell element isolation film 108.

The cell element isolation film 108 may include, for example, at least one of a silicon oxide film, a silicon nitride film, and a silicon oxynitride film. However, the present disclosure is not limited thereto. The cell element isolation film 108 is shown to be formed as one insulating film. However, this is only for convenience of illustration. The present disclosure is not limited thereto. Depending on a spacing between adjacent cell active areas ACT, the cell element isolation film 108 may be formed as one insulating film, or may be formed as a plurality of insulating films.

An upper surface of the cell element isolation film 108 and the upper surface of the substrate 100 are shown as being coplanar with each other in the third direction D3. However, this is only for convenience of illustration. The present disclosure is not limited thereto.

The cell gate structure 110 may be formed in the substrate 100 and the cell element isolation film 108. The cell gate structure 110 may extend in the first direction D1 across the cell element isolation film 108 and the cell active area ACT defined by the cell element isolation film 108.

The cell gate structure 110 is formed in the substrate 100 and the cell element isolation film 108. The cell gate structure 110 may include a cell gate trench 115, a cell gate insulating film 111, a cell gate electrode 112, a cell gate capping pattern 113, and a cell gate capping conductive film 114.

In this regard, the cell gate electrode 112 may act as the wordline WL. Unlike what is shown, the cell gate structure 110 may not include the cell gate capping conductive film 114; that is, the cell gate capping conductive film 114 may be optionally provided.

Although not shown, the cell gate trench 115 may have a relatively deep portion in the cell element isolation film 108 and a relatively shallow portion in the cell active areas ACT. A bottom surface of the wordline WL may be curved. That is, a depth of a portion of the cell gate trench 115 in the cell element isolation film 108 may be greater than a depth of a portion of the cell gate trench 115 in the cell active area ACT.

The cell gate insulating film 111 may extend along a sidewall and a bottom surface of the cell gate trench 115. The cell gate insulating film 111 may extend along a profile of at least a portion of the cell gate trench 115.

For example, the cell gate insulating film 111 may include at least one of silicon oxide, silicon nitride, silicon oxynitride, or a high dielectric constant material having a higher dielectric constant than that of silicon oxide, although embodiments are not limited thereto. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof. The present disclosure is not limited thereto.

The cell gate electrode 112 may be disposed on the cell gate insulating film 111. The cell gate electrode 112 may fill a portion of the cell gate trench 115. The cell gate capping conductive film 114 may extend along an upper surface of the cell gate electrode 112.

The cell gate electrode 112 may include at least one of metal, metal alloy, conductive metal nitride, conductive metal carbonitride, conductive metal carbide, conductive metal silicide, doped semiconductor material, conductive metal oxynitride, and conductive metal oxide. The cell gate electrode 112 may include at least one of, for example, TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrO, RuO and combinations thereof. However, the present disclosure is not limited thereto.

The cell gate capping conductive film 114 may include, but is not limited to, one of polysilicon, polysilicon-germanium, amorphous silicon, and amorphous silicon-germanium.

The cell gate capping pattern 113 may be disposed on the cell gate electrode 112 and the cell gate capping conductive film 114. The cell gate capping pattern 113 may fill a portion of the cell gate trench 115 remaining after the cell gate electrode 112 and the cell gate capping conductive film 114 have been formed therein. The cell gate insulating film 111 is shown as extending along a sidewall of the cell gate capping pattern 113. However, the present disclosure is not limited thereto.

For example, the cell gate capping pattern 113 may include at least one of silicon nitride, silicon oxynitride, silicon oxide, silicon carbonitride, silicon oxycarbonitride, and combinations thereof, although embodiments are not limited thereto.

It is shown that an upper surface of the cell gate capping pattern 113 is coplanar with the upper surface of the cell element isolation film 108 in the third direction D3. However, the present disclosure is not limited thereto.

Although not shown, an impurity doped area may be formed on at least one side of the cell gate structure 110. The impurity doped area may be a source/drain area of the transistor. The impurity doped area may be formed in each of the storage connection area 106b and the bit line connection area 106a.

The bit line structure 140ST may include a cell conductive line 140 and a cell line capping film 144. The cell conductive line 140 may be disposed on the cell element isolation film 108 and the substrate 100 in which the cell gate structure 110 has been formed. The cell conductive line 140 may intersect the cell element isolation film 108 and the cell active area ACT defined by the cell element isolation film 108. The cell conductive line 140 may be formed so as to intersect the cell gate structure 110. In this regard, the cell conductive line 140 may act as the bit line BL.

The cell conductive line 140 may include, for example, at least one of semiconductor material doped with impurities, conductive metal silicide, conductive metal nitride, conductive metal oxide, two-dimensional (2D) material, metal, and metal alloy, although embodiments are not limited thereto. In the semiconductor memory device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂), molybdenum diselenide (MoSe₂), tungsten diselenide (WSe₂), and tungsten disulfide (WS₂). However, the present disclosure is not limited thereto. In other words, the above-described two-dimensional materials are listed only by way of example. The two-dimensional material that may be included in the semiconductor memory device of the present disclosure is not limited to the above-described materials.

The cell conductive line 140 is shown as being formed as a single film. However, this is only for convenience of illustration and the present disclosure is not limited thereto. That is, unlike what is shown, the cell conductive line 140 may include a stack of a plurality of conductive films made of conductive materials.

The cell line capping film 144 may be disposed on the cell conductive line 140. The cell line capping film 144 may extend in the second direction D2 and along an upper surface of the cell conductive line 140. For example, the cell line capping film 144 may include at least one of a silicon nitride film, a silicon oxynitride film, a silicon carbonitride film, and a silicon oxycarbonitride film, although embodiments are not limited thereto.

In the semiconductor memory device according to some embodiments, the cell line capping film 144 may include a silicon nitride film. The cell line capping film 144 is shown as being formed as a single film. However, this is only for convenience of illustration and the present disclosure is not limited thereto.

The bit line contact 146 may be formed between the cell conductive line 140 and the substrate 100. The cell conductive line 140 may be disposed on the bit line contact 146.

The bit line contact 146 may be between the cell conductive line 140 and the substrate 100. The cell conductive line 140 may be disposed on the bit line contact 146. The bit line contact 146 may be formed between the bit line connection area 106a of the cell active area ACT and the cell conductive line 140. The bit line contact 146 may be connected to the bit line connection area 106a.

The bit line contact 146 may electrically connect the cell conductive line 140 and the substrate 100 to each other. In this regard, the bit line contact 146 may act as the direct contact DC. For example, the bit line contact 146 may include at least one of a semiconductor material doped with an impurity, a conductive metal silicide, a conductive metal nitride, a conductive metal oxide, a metal, and a metal alloy, although embodiments are not limited thereto.

In the portion of the cell conductive line 140 on which the bit line contact 146 is formed, the bit line spacer 150 may be formed on the substrate 100 and the cell element isolation layer 105. The bit line spacer 150 may be disposed on sidewalls of the cell conductive line 140, the cell line capping layer 144, and the bit line contact 146. In the remaining portion of the cell conductive line 140 on which the bit line contact 146 is not formed, the bit line spacer 150 may be disposed on the cell insulating layer 130. The bit line spacer 150 may be disposed on the sidewalls of the cell conductive line 140 and the cell line capping layer 144.

The cell insulating film 135 may be formed on the substrate 100 and the cell element isolation film 108. More specifically, the cell insulating film 135 may be disposed on an area of the substrate 100 in which the bit line contact 146 is not formed, and on the cell element isolation film 108. The cell insulating film 135 may be between the substrate 100 and the cell conductive line 140, and between the cell element isolation film 108 and the cell conductive line 140.

The cell insulating film 135 may be formed as a single film. However, as shown in FIGS. 17 and 18, the cell insulating film 135 may be formed as a multi-film structure including a first cell insulating film 136 and a second cell insulating film 137 on the first cell insulating film 136. For example, the first cell insulating film 136 may include a silicon oxide film. The second cell insulating film 137 may include a silicon nitride film. However, the present disclosure is not limited thereto. In another example, unlike what is shown, the cell insulating film 135 may include three or more insulating films.

A storage contact 120 may be between the cell conductive lines 140 adjacent to each other in the first direction D1. The storage contact 120 may overlap a portion of the substrate 100 and the cell element isolation film 108 disposed between adjacent cell conductive lines 140. The storage contact 120 may be connected to the storage connection area 106b of the cell active area ACT. In this regard, the storage contact 120 may act as the buried contact BC. Additionally, the storage contact 120 may act as the storage contact 103 in FIG. 1 to FIG. 15.

The storage contact 120 may include, for example, at least one of semiconductor material doped with impurities, conductive metal silicide, conductive metal nitride, conductive metal carbide, conductive metal carbonitride, conductive metal oxide, metal, and metal alloy.

A storage pad 160 may be disposed on the storage contact 120. The storage pad 160 may be electrically connected to the storage contact 120. In this regard, the storage pad 160 may act as the landing pad LP. Additionally, the storage pad 160 may act as the storage pad 104 in FIG. 1 to FIG. 15.

The storage pad 160 may overlap a portion of an upper surface of the bit line structure 140ST in the third direction D3. For example, the storage pad 160 may include at least one of a semiconductor material doped with impurities, a conductive silicide compound, a conductive metal nitride, a conductive metal carbide, a metal, and a metal alloy, although embodiments are not limited thereto.

A pad isolation insulating film 180 may be formed on the storage pad 160 and the bit line structure 140ST. For example, the pad isolation insulating film 180 may be on the cell line capping film 144. The pad isolation insulating film 180 may define the storage pad 160 as each of a plurality of isolated areas.

The pad isolation insulating film 180 does not cover an upper surface of the storage pad 160. The pad isolation insulating film 180 may fill a pad isolation recess. The pad isolation recess may electrically isolate adjacent storage pads 160 from each other. For example, the upper surface of the storage pad 160 may be coplanar with an upper surface of the pad isolation insulating film 180 in the third direction D3.

The pad isolation insulating film 180 includes an insulating material and may electrically insulate adjacent ones of the plurality of storage pads 160 from each other. For example, the pad isolation insulating film 180 may include at least one of a silicon oxide film, a silicon nitride film, a silicon oxynitride film, a silicon oxycarbonitride film, and a silicon carbonitride film. However, the present disclosure is not limited thereto.

The etch stop film 105 may be disposed on the storage pad 160 and the pad isolation insulating film 180. The capacitor structure 300 may be disposed on the storage pad 160. The capacitor structure 300 may be electrically connected to the storage pad 160. The capacitor structure 300 may be the capacitor structure 300 in FIG. 2, FIG. 11, and FIG. 17.

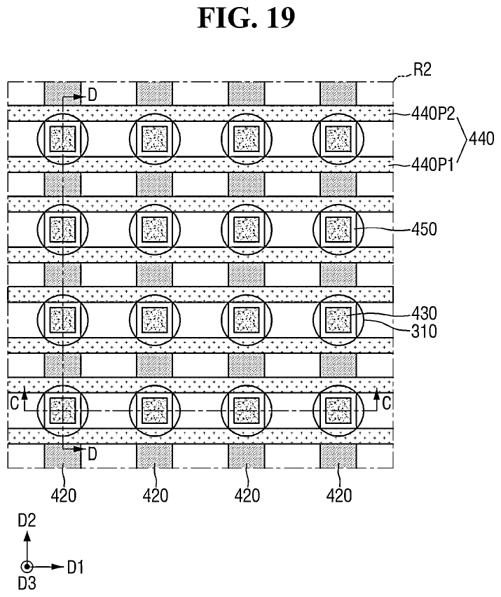

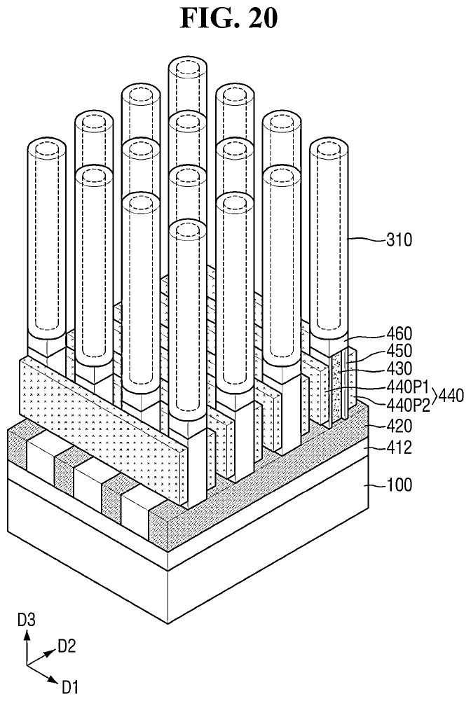

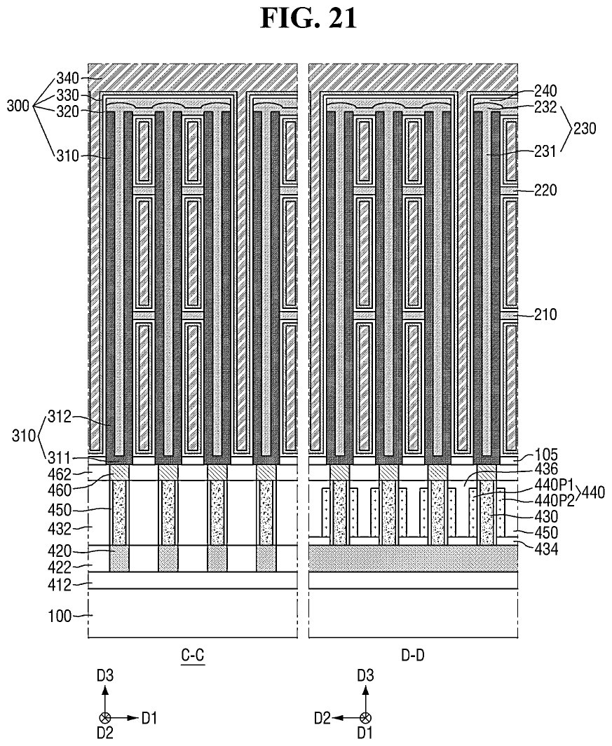

FIG. 19 is a schematic layout diagram (i.e., top plan view) for illustrating a semiconductor memory device according to some embodiments. FIG. 20 is a schematic perspective view for illustrating a semiconductor memory device according to some embodiments. FIG. 21 is a schematic cross-sectional view of the semiconductor memory device shown in FIG. 19, taken along lines C-C and D-D in FIG. 19.

Referring to FIG. 19 to FIG. 21, the semiconductor memory device according to some embodiments includes the substrate 100, a plurality of first conductive lines 420, a channel layer 430, a gate electrode 440, a gate insulating film 450 and the capacitor structure 300. The semiconductor memory device according to some embodiments may be a memory device including a vertical channel transistor (VCT). The vertical channel transistor may refer to a structure in which a channel length of the channel layer 430 extends from the substrate 100 along a vertical direction (i.e., the third direction D3).

A lower insulating layer 412 may be disposed on the substrate 100 between the substrate 100 and the plurality of first conductive lines 420. The plurality of first conductive lines 420 may be disposed on the lower insulating layer 412 and may be spaced apart from each other in the first direction D1 and extend longitudinally in the second direction D2. A plurality of first insulating patterns 422 may be disposed on the lower insulating layer 412 so as to fill a space between adjacent ones of the plurality of first conductive lines 420. The plurality of first insulating patterns 422 may extend in the second direction D2. An upper surface of the plurality of first insulating patterns 422 may be positioned at the same vertical level as that of an upper surface of the plurality of first conductive lines 420; that is, the upper surface of the plurality of first insulating patterns 422 and the upper surface of the plurality of first conductive lines 420 may be coplanar in the third direction D3. Each of the plurality of first conductive lines 420 may function as a bit line.

Each of the plurality of first conductive lines 420 may include at least one of a semiconductor material doped with impurities, a metal, a conductive metal nitride, a conductive metal silicide, a conductive metal oxide, or a combination thereof. For example, each of the plurality of first conductive lines 420 may include at least one of polysilicon doped with impurities, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but may not be limited thereto. Each of the plurality of first conductive lines 420 may include a single layer or multiple layers made of the aforementioned materials. In some embodiments, each of the plurality of first conductive lines 420 may include graphene, carbon nanotube, or a combination thereof.

The channel layer 430 may have a matrix form in which channels are spaced apart from each other in each of the first direction D1 and the second direction D2 and are disposed on the plurality of first conductive lines 420, respectively. Each channel of the channel layer 430 may have a first width according to the first direction D1 and a first vertical dimension according to the third direction D3, wherein the first vertical dimension may be greater than the first width. In this regard, the third direction D3 may intersect the first direction D1 and the second direction D2, and may be, for example, a direction perpendicular to the upper surface of the substrate 100. For example, the first vertical dimension may be about 2 to 10 times of the first width. However, the disclosure is not limited thereto. A bottom portion of each channel of the channel layer 430 may function as a third source/drain area (not shown), while a top portion of each channel of the channel layer 430 may function as a fourth source/drain area (not shown). A portion of each channel of the channel layer 430 between the third and fourth source/drain areas may function as a channel area (not shown).

In some embodiments, the channel layer 430 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof, although embodiments are not limited thereto. The channel layer 430 may include a single layer or multiple layers made of the oxide semiconductor. In some examples, the channel layer 430 may have a bandgap energy greater than that of silicon. For example, the channel layer 430 may have a bandgap energy of about 1.5 electron volts (eV) to about 5.6 eV. For example, the channel layer 430 may have optimal channel performance when the channel layer 430 has a bandgap energy of about 2.0 eV to 4.0 eV. For example, the channel layer 430 may be made of polycrystalline or amorphous, but may not be limited thereto. In some embodiments, the channel layer 430 may include graphene, carbon nanotubes, or a combination thereof.

The gate electrode 440 may extend in the first direction D1 and may be formed on both side walls of each channel of the channel layer 430. The gate electrode 440 may include a first sub-gate electrode 440P1 facing toward a first side wall of the channel layer 430, and a second sub-gate electrode 440P2 facing toward a second side wall opposite to the first side wall of the channel layer 430. As one channel of the channel layer 430 is between the first sub-gate electrode 440P1 and the second sub-gate electrode 440P2, the semiconductor memory device may have a dual gate transistor structure. However, the technical spirit of the present disclosure is not limited thereto. The second sub-gate electrode 440P2 may be omitted and thus only the first sub-gate electrode 440P1 facing toward the first side wall of the channel layer 430 may be formed, so that the semiconductor memory device may be implemented to a single gate transistor structure. Description of a material of the gate electrode 440 may be the same as the description of the cell gate electrode 112.

The gate insulating film 450 surrounds (i.e., extends around) a side wall of each channel of the channel layer 430 and may be interposed between each channel of the channel layer 430 and the gate electrode 440. For example, as shown in FIG. 19, an entirety of a side wall of each channel of the channel layer 430 may be surrounded with the gate insulating film 450, and a portion of a side wall of the gate electrode 440 may contact the gate insulating film 450. In other embodiments, the gate insulating film 450 may extend in an extension direction of the gate electrode 440, that is, the first direction D1, and only two side walls facing toward the gate electrode 440 among all of side walls of each channel of the channel layer 430 may contact the gate insulating film 450. In some embodiments, the gate insulating film 450 may be embodied as a silicon oxide film, a silicon oxynitride film, a film made of a high dielectric constant material having a dielectric constant higher than that of the silicon oxide film, or a combination thereof.

A plurality of second insulating patterns 432 may extend along the second direction D2 and may be disposed on the plurality of first insulating patterns 422, respectively. Each channel of the channel layer 430 may be between two adjacent second insulating patterns 432 of the plurality of second insulating patterns 432. Further, a first buried layer 434 and a second buried layer 436 may be between two adjacent second insulating patterns 432 and in a space between two adjacent channels of the channel layer 430. The first buried layer 434 may be in a bottom portion of a space between two adjacent channels of the channel layer 430. The second buried layer 436 may at least partially fill a remainder of the space between the two adjacent channels of the channel layer 430 and may be disposed on the first buried layer 434. An upper surface of the second buried layer 436 may be coplanar with an upper surface of the channel layer 430 in the third direction D3, and the second buried layer 436 may cover an upper surface of the gate electrode 440. Alternatively, each of the plurality of second insulating patterns 432 and each of the plurality of first insulating patterns 422 may constitute a continuous material layer and thus may be monolithic. Alternatively, the second buried layer 436 and the first buried layer 434 may constitute a continuous material layer and thus may be monolithic.

Each capacitor contact 460 may be disposed on each channel of the channel layer 430. Each capacitor contact 460 may vertically overlap each channel of the channel layer 430. Thus, the capacitor contacts 460 may be arranged in a matrix form in which the capacitor contacts 460 are spaced apart from each other in each of the first direction D1 and the second direction D2. The capacitor contact 460 may include at least one of polysilicon doped with impurities, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but may not be limited thereto. An upper insulating layer 462 may surround (i.e., extend around) a side wall of each capacitor contact 460 and may be disposed on the plurality of second insulating patterns 432 and the second buried layer 436.

The etch stop film 105 may be disposed on the upper insulating layer 462. The capacitor structure 300 may be disposed on the etch stop film 105. Each of the etch stop film 105 and the capacitor structure 300 may be the etch stop film 105 and the capacitor structure 300 shown in FIG. 2, FIG. 11, and FIG. 17, respectively.

In illustrative embodiments, the lower electrode 310 may vertically overlap the capacitor contact 460. The lower electrodes 310 may be arranged in a matrix form in which the lower electrodes 310 are spaced apart from each other in each of the first direction D1 and the second direction D2. Alternatively, a landing pad (not shown) may be further disposed between the capacitor contact 460 and the lower electrode 310, and thus, the lower electrodes 310 may be arranged in a hexagonal shape.

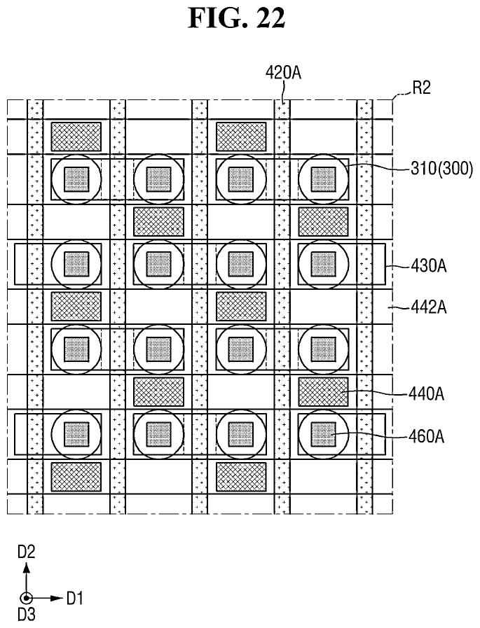

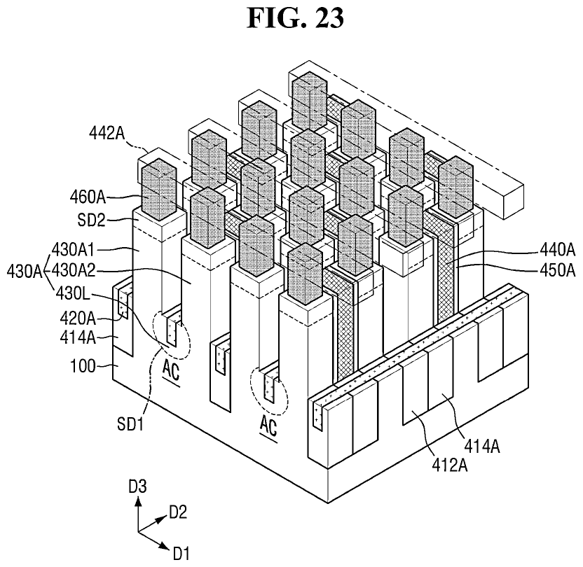

FIG. 22 is a schematic layout diagram (i.e., top plan view) for illustrating a semiconductor memory device according to some embodiments. FIG. 23 is a schematic perspective view for illustrating a semiconductor memory device according to some embodiments.

Referring to FIG. 22 and FIG. 23, the semiconductor memory device according to some embodiments may include the substrate 100, a plurality of first conductive lines 420A, a channel structure 430A, a contact gate electrode 440A, a plurality of second conductive lines 442A, and the capacitor structure 300. The semiconductor memory device according to some embodiments may be a memory device including a vertical channel transistor (VCT).

A plurality of active areas AC may be defined in the substrate 100 by a first element isolation pattern 412A and a second element isolation pattern 414A. The channel structure 430A may be disposed in each of the active areas AC. The channel structure 430A may include a first active pillar 430A1 and a second active pillar 430A2 extending in a vertical direction (i.e., the third direction D3), and a connector 430L connected to a bottom portion of the first active pillar 430A1 and a bottom portion of the second active pillar 430A2. A first source/drain area SD1 may be disposed in the connector 430L. A second source/drain area SD2 may be disposed in a top portion of each of the first and second active pillars 430A1 and 430A2. Each of the first active pillar 430A1 and the second active pillar 430A2 may constitute an independent unit memory cell.

The plurality of first conductive lines 420A may extend in a direction intersecting the plurality of active areas AC. For example, the plurality of first conductive lines 420A may extend in the second direction D2. One of the plurality of first conductive lines 420A may be disposed on the connector 430L and between the first active pillar 430A1 and the second active pillar 430A2. One first conductive line 420A may be disposed on the first source/drain area SD1. Another first conductive line 420A adjacent to said one first conductive line 420A may be disposed between two channel structures 430A. One first conductive line 420A of the plurality of first conductive lines 420A may function as a common bit line commonly included in two unit memory cells respectively corresponding to the first active pillar 430A1 and the second active pillar 430A2 respectively disposed on both sides of said one first conductive line 420A.

One contact gate electrode 440A may be between two channel structures 430A adjacent to each other in the second direction D2. For example, the contact gate electrode 440A may be between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 respectively disposed on both (facing) side walls thereof. The gate insulating film 450A may be between the contact gate electrode 440A and the first active pillar 430A1 and between the contact gate electrode 440A and the second active pillar 430A2. The plurality of second conductive lines 442A may extend in the first direction D1. Each of the plurality of second conductive lines 442A may be on an upper surface of each contact gate electrode 440A. Each of the plurality of second conductive lines 442A may function as a wordline of a semiconductor memory device.

A capacitor contact 460A may be disposed on the channel structure 430A. The capacitor contact 460A may be on the second source/drain area SD2. The capacitor structure 300 may be on the capacitor contact 460A. The capacitor structure 300 may be embodied as the capacitor structure 300 in FIG. 2, FIG. 11, and FIG. 17.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor memory device, comprising:
a storage pad on a substrate;
a lower electrode on the storage pad and including a trench defined by a bottom and sidewalls of the lower electrode;
a lower support pattern including a first portion in the trench, and a second portion on an upper surface of the lower electrode and contacting the first portion;
an upper support pattern on an upper surface of the lower support pattern;
a capacitor dielectric film on the lower electrode, the lower support pattern, and the upper support pattern; and
an upper electrode on the capacitor dielectric film.

2. The semiconductor memory device of claim 1, wherein the lower support pattern and the upper support pattern include the same material.

3. The semiconductor memory device of claim 1, wherein the lower support pattern and the upper support pattern include different materials.

4. The semiconductor memory device of claim 1, wherein an upper surface of the second portion of the lower support pattern includes a convex portion facing away from the substrate.

5. The semiconductor memory device of claim 1, wherein a first thickness in a third direction perpendicular to an upper surface of the substrate of a portion of the lower electrode defining a bottom surface of the trench is different from a second thickness in a first direction parallel to the upper surface of the substrate of a portion of the lower electrode defining a sidewall of the trench.

6. The semiconductor memory device of claim 1, wherein a lowermost surface of the second portion of the lower support pattern is lower than the upper surface of the lower electrode in a third direction perpendicular to an upper surface of the substrate, relative to the upper surface of the substrate.

7. The semiconductor memory device of claim 1, wherein a lowermost surface of the second portion of the lower support pattern is coplanar with the upper surface of the lower electrode in a third direction perpendicular to an upper surface of the substrate.

8. The semiconductor memory device of claim 1, wherein the lower support pattern and the lower electrode include different materials.

9. The semiconductor memory device of claim 1, wherein a width of the trench in a first direction parallel to an upper surface of the substrate increases and then decreases as the trench extends in a third direction toward the substrate.

10. A semiconductor memory device, comprising:
a storage pad on a substrate;
a lower electrode on the storage pad and including a trench defined by a bottom and sidewalls of the lower electrode;
a lower support pattern in the trench and extending along an upper surface of the lower electrode and along an outer wall of a top portion of the lower electrode in a first direction parallel to an upper surface of the substrate;
a capacitor dielectric film on the lower electrode and the lower support pattern; and
an upper electrode on the capacitor dielectric film.

11. The semiconductor memory device of claim 10, wherein the lower support pattern includes silicon carbonitride (SiCN).

12. The semiconductor memory device of claim 10, wherein an upper surface of the lower support pattern includes a convex portion facing away from the substrate in a third direction perpendicular to the upper surface of the substrate.

13. The semiconductor memory device of claim 10, wherein a width of the trench in the first direction decreases or is constant as the trench extends toward the substrate in a third direction perpendicular to the upper surface of the substrate.

14. The semiconductor memory device of claim 10, wherein a width of the trench in the first direction increases and then decreases as the trench extends toward the substrate in a third direction perpendicular to the upper surface of the substrate.

15. The semiconductor memory device of claim 10, further comprising an upper support pattern extending in the first direction on an upper surface of the lower supporter pattern.

16. The semiconductor memory device of claim 10, further comprising a bit line structure on the substrate, and a cell gate structure in the substrate and intersecting the bit line structure, wherein the storage pad is on a side surface of the bit line structure and is electrically connected to the substrate.

17. The semiconductor memory device of claim 10, further comprising a support pattern on a side wall of the lower electrode.

18. A method for manufacturing a semiconductor memory device, the method comprising:
sequentially forming an etch stop film and a mold film on a substrate;
forming a lower electrode hole extending, in a third direction perpendicular to an upper surface of the substrate, through the etch stop film and the mold film;
forming a lower electrode extending in the third direction along sidewalls and on a bottom of the lower electrode hole and including a trench defined by a bottom and sidewalls of the lower electrode;
forming a lower support pattern at least partially filling the trench and extending in a first direction parallel to the upper surface of the substrate along an upper surface of the mold film;
forming an upper support pattern on the lower support pattern;
removing the mold film to expose a portion of the lower electrode, a portion of the lower support pattern, and a portion of the upper support pattern;
forming a capacitor dielectric film on the exposed portion of the lower electrode, the exposed portion of the lower support pattern, and the exposed portion of the upper support pattern; and
forming an upper electrode on the capacitor dielectric film.

19. The method of claim 18, further comprising, after forming the lower electrode, etching a portion of the mold film to expose a top portion of the lower electrode,
wherein forming the lower support pattern further includes forming the lower support pattern on the exposed top portion of the lower electrode.

20. The method of claim 18, wherein the lower support pattern and the upper support pattern include the same material.
